(19) United States
(12) Patent Application Publication
(10) Pub. No.: US 2008/0006884 A1
(43) Pub. Date: Jan. 10, 2008

(54) Semiconductor device and method of manufacturing the same

(76) Inventor: Atsushi Yagishita, Somers, NY (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/802,529

(22) Filed: May 23, 2007

(30) Foreign Application Priority Data
May 24, 2006 (JP) 2006-144491

(51) Int. Cl. H01L 27/088; H01L 21/8234

(52) U.S. Cl. 257/384; 438/296; 257/E21.619; 257/E21.622; 257/E21.628; 257/E27.06

(57) ABSTRACT

A semiconductor device includes a MISFET, the MISFET having a shallow trench insulator (STI) formed in a surface layer of a semiconductor substrate to define a device forming region, a gate electrode formed above the device forming region via a gate insulating film, impurity diffusion layers composing a source and a drain formed in the surface layer of the device forming region using SiGe so as to sandwich the gate electrode, and a first metal silicide formed on the surfaces of the impurity diffusion layers. The surface height of the STI is substantially the same as the height of the first metal silicide.

### CROSS REFERENCE TO RELATED APPLICATIONS

This application claims benefit of priority under 35USC §119 to Japanese patent application No. 2006-144491, filed on May 24, 2006, the contents of which are incorporated by reference herein.

### BACKGROUND OF THE INVENTION

1. Field of the Invention

The present invention relates to a semiconductor device and a method of manufacturing the same.

2. Related Art

A variety of technologies have been proposed in order to improve the drive current of a metal insulator semiconductor field effect transistor (MISFET) which is element-isolated using a shallow trench insulator (STI). In the case of a p-type metal oxide semiconductor field effect transistor (MOSFET), for example, there is proposed a technology for providing a concave portion (recess) on the surface layer of a semiconductor substrate in a region wherein impurity diffusion layers for a source and a drain are formed and epitaxially growing SiGe in the recess.

In the related art, however, facets occur in SiGe at edges of the STI. For this reason, a silicide grows abnormally in the silicidation of the source and drain. Consequently, junction leakage increases, leading to another problem that a characteristic of a short channel device is impaired.

### SUMMARY OF THE INVENTION

According to a first aspect of the present invention, there is provided a semiconductor device comprising a MISFET, the MISFET including:

a shallow trench insulator (STI) formed in a surface layer of a semiconductor substrate to define a device forming region;

a gate electrode formed above the device forming region via a gate insulating film;

impurity diffusion layers composing a source and a drain formed in the surface layer of the device forming region using SiGe or SiC so as to sandwich the gate electrode; and

a first metal silicide formed on the surfaces of the impurity diffusion layers;

wherein the surface height of the STI is substantially the same as the height of the first metal silicide.

According to a second aspect of the present invention, there is provided a method of manufacturing a semiconductor device comprising:

forming a gate electrode of a conductive material above a device forming region of a semiconductor substrate via a gate insulating film;

forming concave portions in an impurity diffusion layer forming region by selectively removing a surface layer of the device forming region so as to sandwich the gate electrode as viewed from the top;

forming SiGe layers composing a source and a drain in impurity diffusion layer forming regions by epitaxially growing SiGe onto the concave portions; and

forming a shallow trench insulator (STI) to isolate the device forming region after forming the SiGe layers.

According to a third aspect of the present invention, there is provided a method of manufacturing a semiconductor device comprising:

forming a gate electrode of a conductive material above a device forming region of a semiconductor substrate via a gate insulating film;

forming concave portions in an impurity diffusion layer forming region by selectively removing a surface layer of the device forming region so as to sandwich the gate electrode as viewed from the top;

forming SiC layers composing a source and a drain in impurity diffusion layer forming regions by epitaxially growing SiC onto the concave portions; and

forming a shallow trench insulator (STI) to isolate the device forming region after forming the SiC layers.

According to a fourth aspect of the present invention, there is provided a method of manufacturing a semiconductor device comprising:

provisionally forming a gate electrode above a device forming region of a semiconductor substrate via a gate insulating film;

forming concave portions in an impurity diffusion layer forming region by selectively removing a surface layer of the device forming region so as to sandwich the provisional gate electrode as viewed from the top;

forming SiGe layers composing a source and a drain in the impurity diffusion layer forming region by epitaxially growing SiGe onto the concave portions;

forming a shallow trench insulator (STI) to isolate the device forming region after forming the SiGe layers; and

forming a gate electrode after removing the provisional gate electrode, filling a metal material in a trench thus formed, and flattening a surface of the metal filled in the trench.

According to a fifth aspect of the present invention, there is provided a method of manufacturing a semiconductor device comprising:

provisionally forming a gate electrode above a device forming region of a semiconductor substrate via a gate insulating film;

forming concave portions in an impurity diffusion layer forming region by selectively removing a surface layer of the device forming region so as to sandwich the provisional gate electrode as viewed from the top;

forming SiC layers composing a source and a drain in the impurity diffusion layer forming region by epitaxially growing SiC onto the concave portions;

forming a shallow trench insulator (STI) to isolate the device forming region after forming the SiC layers; and

forming a gate electrode after removing the provisional gate electrode, filling a metal material in a trench thus formed, and flattening a surface of the metal filled in the trench.

### BRIEF DESCRIPTION OF THE DRAWINGS

In the accompanying drawings:

FIG. 1 is a schematic cross-sectional view illustrating an approximate configuration of the first embodiment of a semiconductor device in accordance with the present invention;

FIG. 2 is a schematic cross-sectional view illustrating a comparative example of a semiconductor device according to the related art;

FIG. 3 is a schematic cross-sectional view illustrating another comparative example of a semiconductor device according to the related art;

FIGS. 4 to 7 are schematic cross-sectional views intended to explain a method of manufacturing the semiconductor device illustrated in FIG. 1;

FIGS. 8 to 13 are partial perspective views intended to explain a method of manufacturing the semiconductor device illustrated in FIG. 1;

FIG. 14 is a schematic cross-sectional view illustrating an example of modification of the semiconductor device illustrated in FIG. 1;

FIG. 15 is a schematic cross-sectional view illustrating an approximate configuration of the second embodiment of a semiconductor device in accordance with the present invention;

FIGS. 16 to 21 are partial perspective views intended to explain a method of manufacturing the semiconductor device illustrated in FIG. 15;

FIG. 22 is a schematic cross-sectional view illustrating an example of modification of the semiconductor device illustrated in FIG. 15;

FIG. 23 is a schematic cross-sectional view illustrating an approximate configuration of the third embodiment of a semiconductor device in accordance with the present invention;

FIGS. 24 to 26 are schematic cross-sectional views intended to explain a method of manufacturing the semiconductor device illustrated in FIG. 23;

FIGS. 27 to 33 are partial perspective views intended to explain a method of manufacturing the semiconductor device illustrated in FIG. 23;

FIG. 34 is a schematic cross-sectional view illustrating an example of modification of the semiconductor device illustrated in FIG. 23;

FIG. 35 is a schematic cross-sectional view illustrating an approximate configuration of the fourth embodiment of a semiconductor device in accordance with the present invention;

FIG. 36 is a schematic cross-sectional view illustrating an example of modification of the semiconductor device illustrated in FIG. 35;

FIG. 37 is a schematic view illustrating an example wherein a gate electrode made of W/TiN is formed in a p-type MISFET using a damascene process; and

FIG. 38 is a schematic view illustrating an example wherein a gate electrode made of W/TiN is formed in an n-type MISFET using a damascene process.

### DETAILED DESCRIPTION OF THE INVENTION

Some embodiments of the present invention will hereinafter be described with reference to the accompanying drawings. In the drawings, like parts are given like reference numerals and their descriptions are omitted as appropriate.

### (1) First Embodiment

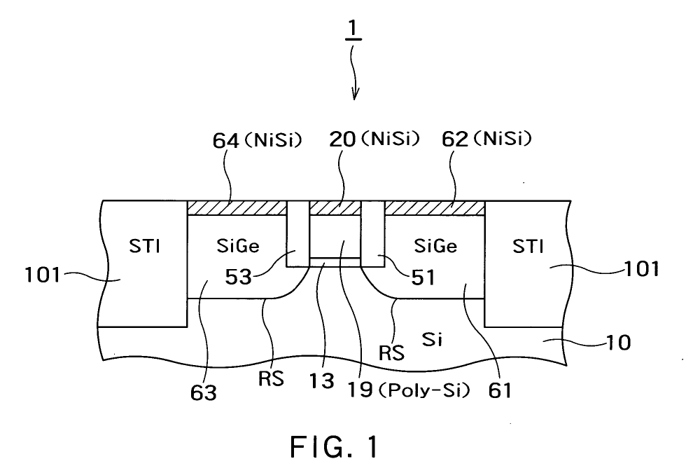

FIG. 1 is a schematic cross-sectional view illustrating an approximate configuration of the first embodiment of a semiconductor device in accordance with the present invention.

A semiconductor device 1 is provided with a pMOSFET formed in a device region defined by an STI 101 for device isolation formed in the surface layer of a silicon (Si) substrate 10. The gate electrode 19 of the pMOSFET is formed above the Si substrate 10 via a gate oxide film 13 using a conductive material which is a polysilicon in the present embodiment. Side walls 51 and 53 are formed on the sides of the gate oxide film 13 and the gate electrode 19 using an insulating material which is SiN in the present embodiment. Concave portions (recess) RS are formed in the surface layer of the substrate 10, which is an impurity diffusion layer forming region, between the side wall 51 and the STI 101 and between the side wall 53 and the STI 101, so as to sandwich the gate electrode 19. The concave portions RS are formed so as to underrun the side walls 51 and 53 so that a narrow channel region is formed in the surface layer of the substrate immediately underneath the gate electrode 19. In addition, impurity diffusion layers 61 and 63 are formed by filling SiGe in the concave portions RS by the epitaxial growth of SiGe, so that each layer configures a source or a drain.

Metal silicides, which are NiSi 20, NiSi 62 and NiSi 64 in the present embodiment, are respectively formed on the surfaces of the gate electrode 19 and the impurity diffusion layers 61 and 63. In the present embodiment, the NiSi 62 and 64 correspond to, for example, a first metal silicide and the NiSi 20 corresponds to, for example, a second metal silicide.

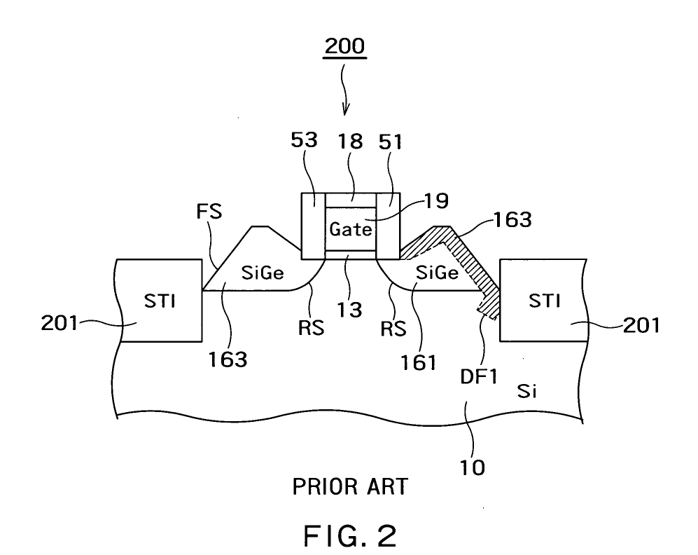

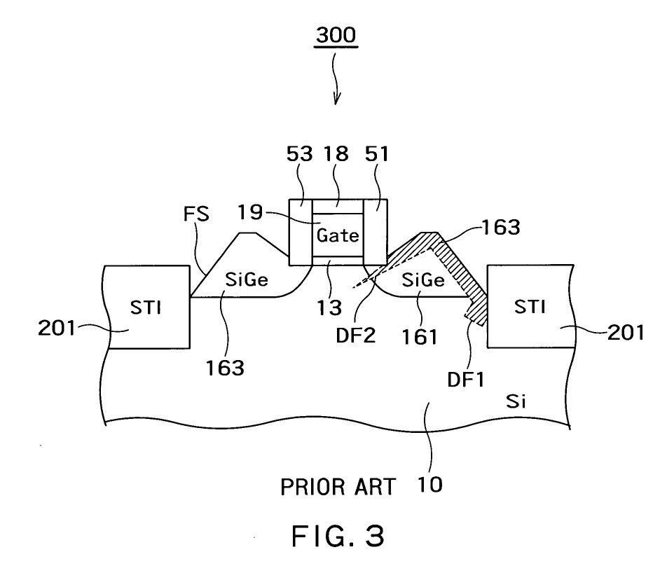

The first feature of the semiconductor device 1 illustrated in FIG. 1 is that the surfaces of the silicides 62 and 64 on the surfaces of the impurity diffusion layers 61 and 63 of the source and drain are flush with the surface of the STI 101. Consequently, the top surface heights of the silicides 62 and 64 are substantially the same as that of the STI 101. In addition, the second feature of the semiconductor device 1 illustrated in FIG. 1 is that the top surface height of the metal silicide 20 on the surface of the gate electrode 19 is also substantially the same as that of the STI 101. In this way, the semiconductor device 1 of the present embodiment is structured to have no SiGe facets at edges of the STI 101. Accordingly, the semiconductor device 1 has been significantly improved in terms of both a characteristic of a short channel device and a junction leakage characteristic, when compared with conventional semiconductor devices. Now, these features will be described more specifically by referring to FIGS. 2 and 3.

Both semiconductor devices 200 and 300 illustrated in FIGS. 2 and 3, respectively, are specific examples of semiconductor devices according to the related art. In either case of these semiconductor devices, facets FS are present at edges of an STI 201 on the periphery of impurity diffusion layers 161 and 163 formed by filling concave portions RS with SiGe by epitaxial growth. For this reason, a metal silicide grows abnormally at edges of the STI 201 in the silicidation of the surfaces of the impurity diffusion layers 161 and 163 and one end DF1 of the metal silicide advances into the surface layer of an Si substrate 10 beyond the bottom surface of the concave portion RS, as indicated by, for example, a reference numeral 163 in FIG. 2, thus causing the problem that junction leakage increases. Furthermore, in the example illustrated in FIG. 3, the metal silicide 163 is formed so as to extend in such a manner that the other end DF2 thereof breaks through a part of the impurity diffusion layer 161 immediately underneath a side wall 51 and reaches a channel region, thus causing the problem that a characteristic of a short channel device is impaired.

In contrast, according to the semiconductor device 1 of the present embodiment, no facets are formed between the impurity diffusion layer 61 and the STI 101 and between the impurity diffusion layer 63 and the STI 101. It is thus understood that the semiconductor device 1 has been significantly improved in terms of both a junction leakage characteristic and a characteristic of a short channel device, when compared with semiconductor devices according to the related art.

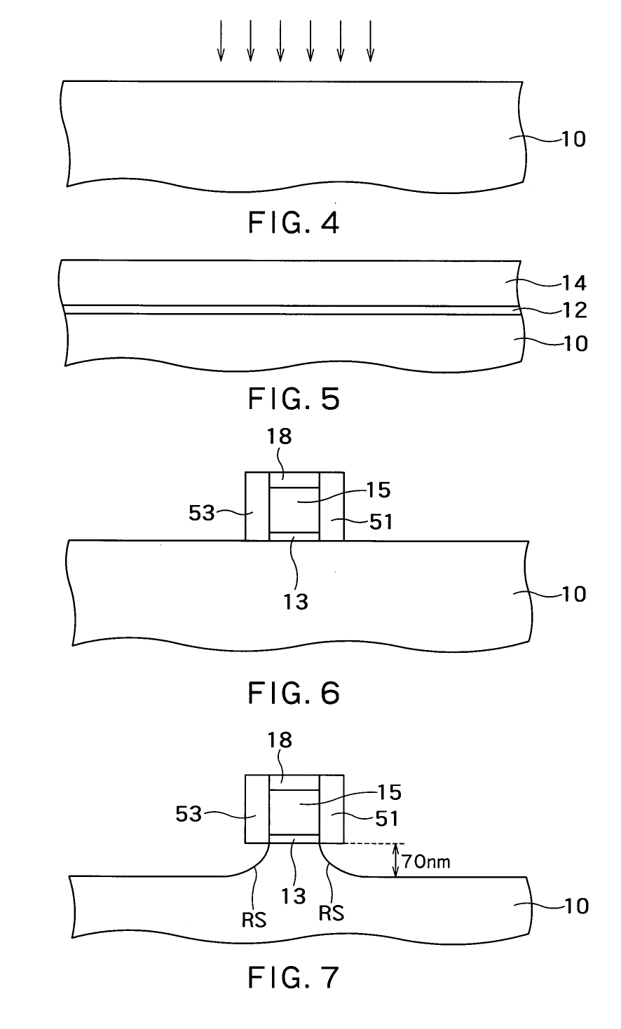

Now, an explanation will be made of a method of manufacturing the semiconductor device 1 which produces such an effect as described above, by referring to FIGS. 4 to 14. FIGS. 4 to 7 are schematic cross-sectional views intended to explain a method of manufacturing the semiconductor device 1 illustrated in FIG. 1 and FIGS. 8 to 13 are partial perspective views intended to explain a method of manufacturing the semiconductor device illustrated in FIG. 1.

First, an Si substrate 10 is prepared and after implanting impurity ions, for example, phosphorous (P) ions in a region where a channel is to be formed, as illustrated in FIG. 4, the ions are diffused by heat treatment to perform channel doping. In the present embodiment, dosage is adjusted so that the channel concentration is 1E19 cm⁻³.

Next, after forming an insulating film, for example, an oxide film 12 on the surface of the Si substrate 10, as illustrated in FIG. 5, a gate polysilicon 14 which is a first layer is deposited to a thickness of approximately 150 nm.

Then, an SiO₂ film, which will serve as a hard mask, is deposited on the gate polysilicon 14 to a thickness of approximately 50 nm and processed to produce a gate electrode pattern by patterning using a resist or a hard mask, thus forming a gate oxide film 13, a gate electrode 15 and an SiO₂ film 18, as illustrated in FIG. 6. Thereafter, approximately 40 nm thick side walls 51 and 53 are formed by depositing SiN over the entire surface of the semiconductor device and etching back the deposited SiN.

Then, as illustrated in FIG. 7, the surface of the Si substrate 10 is selectively removed in a self-aligned manner by chemical dry etching (CDE) or the like using the gate electrode 15 and the gate side walls 51 and 53 as masks, to form approximately 70 nm deep concave portions RS.

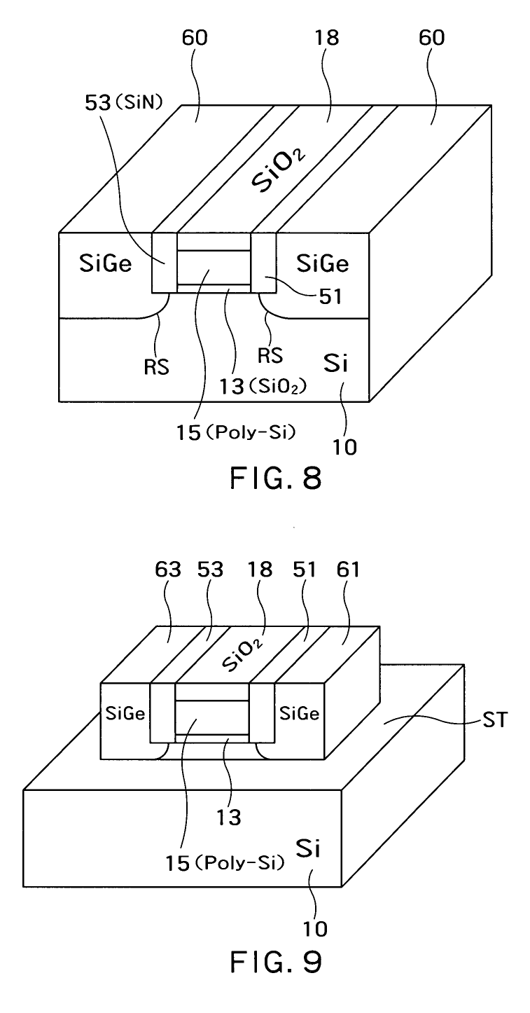

Next, SiGe is epitaxially grown in source and drain forming regions, so as to fill the concave portions RS. Since the top face of the gate electrode 15 is covered with the hard mask made of the SiO₂ film 18 at this point, epitaxial growth never takes place on the gate electrode 15. SiGe is overgrown and the surface thereof is flattened by chemical mechanical polishing (CMP), as illustrated in the partial perspective view of FIG. 8.

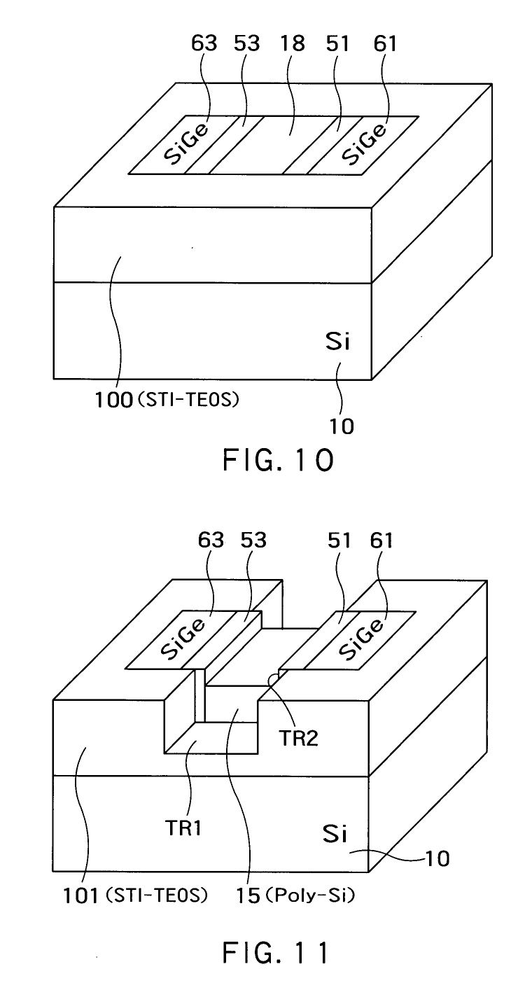

Then, after forming a resist adapted to the shape of a device forming region, a shallow trench ST for device isolation is formed by selectively removing the gate pattern, the side walls 51 and 53 and the SiGe 60 by performing a reactive ion etching (RIE) process, as illustrated in FIG. 9.

In addition, an STI 100 is formed by filling a TEOS insulating film in the formed ST and flattening the surface thereof by CMP, as illustrated in FIG. 10.

As described above, according to the present embodiment, it is possible to prevent SiGe facets from occurring at edges of the STI since the STI is formed after the formation of the gate pattern and the SiGe layers of the source and drain. Accordingly, it is possible to provide a semiconductor device which has been significantly improved in terms of both a junction leakage characteristic and a characteristic of a short channel device.

Subsequently, there is performed, for example, gate electrode processing intended to enable the connection of isolated gate electrodes to each other. More specifically, a trench TR1 is first formed in a partial region of the STI, a trench TR2 is formed above the gate electrode pattern, and the top face of a first-layer gate electrode 15 is exposed, as illustrated in FIG. 11.

Next, a gate electrode material for a second layer, which is polysilicon in the present embodiment, is deposited so as to fill the trenches TR1 and TR2 and the surfaces thereof are flattened by CMP, as illustrated in FIG. 12. It should be noted that in the present embodiment, a lower part of the portion configuring the gate electrode, which is sandwiched by the impurity diffusion layers of the source and drain, is referred to as a first-layer gate electrode. In addition, a part overlaid on the first-layer gate electrode and formed on the first-layer gate electrode and on the trench TR1 is referred to as a second-layer gate electrode.

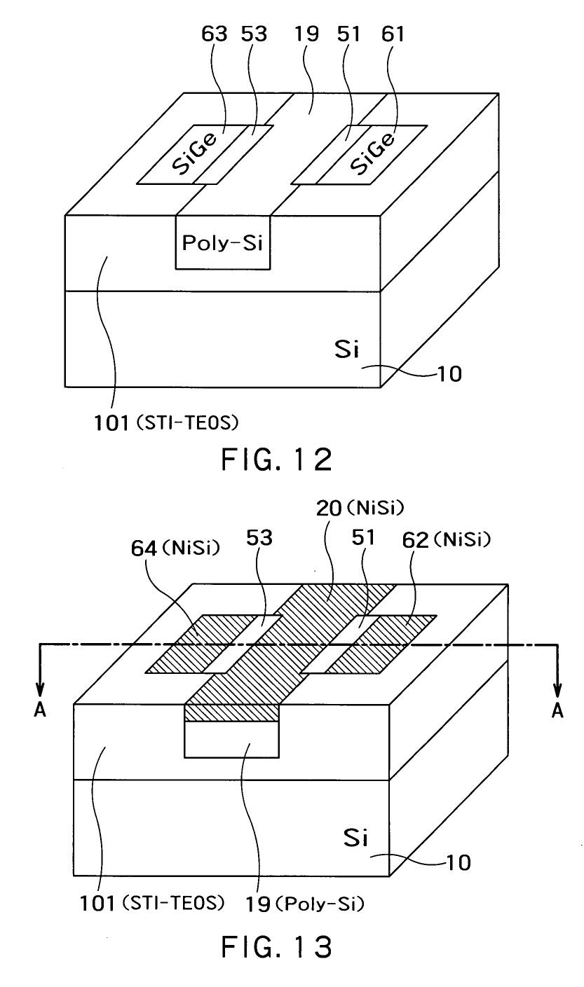

Finally, the semiconductor device 1 illustrated in FIG. 1 is formed by sputtering a metal, for example, Ni onto the surface of the semiconductor device and simultaneously attaching metal silicides to the surfaces of the gate electrode 19 and the impurity diffusion layers 61 and 63 of the source and drain by annealing treatment, as illustrated in FIG. 13. Note here that the cross-section along the line A-A shown in FIG. 13 corresponds to the cross-sectional view of FIG. 1.

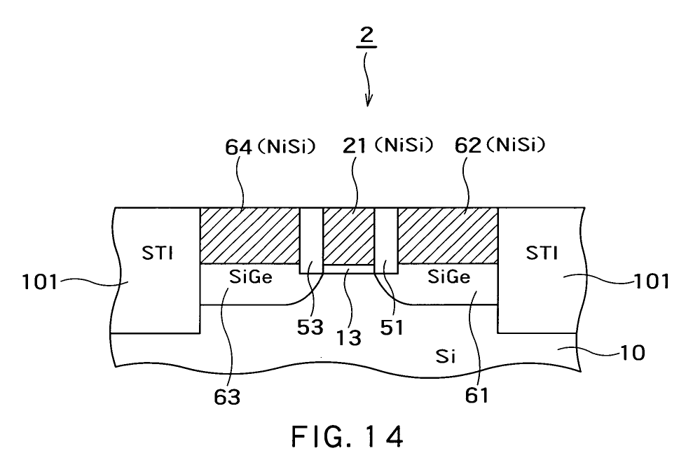

It is also possible to provide a semiconductor device 2 provided with a fully-silicided gate electrode 21 by fully siliciding the gate electrode in the step described with reference to FIG. 13, as illustrated in FIG. 14. In the semiconductor device 2 illustrated in FIG. 14, the gate electrode 21 also corresponds to, for example, a second metal silicide.

According to the semiconductor device manufacturing method of the present embodiment, since the semiconductors of gate, source and drain portions can be simultaneously subjected to a silicide reaction, it is possible to reduce the number of process steps accordingly. Furthermore, even if the semiconductors are subjected to a full silicidation reaction, the silicides of the source and drain portions never grow too deeply. In other words, there are no possibilities that the silicides are formed deeper than the diffusion layers.

In the above-described manufacturing method, a damascene process may be used rather than full silicidation when forming the gate electrode. More specifically, it is possible to form a gate electrode made of metal material by removing the gate polysilicon 19, filling the metal material in the trench thus formed, and flattening the trench by CMP in the manufacturing step illustrated in FIG. 12. In this case, control of the work function (i.e., the threshold of a transistor) of the gate electrode becomes easy since a pure metal other than a silicide can be used as the metal material.

### (2) Second Embodiment

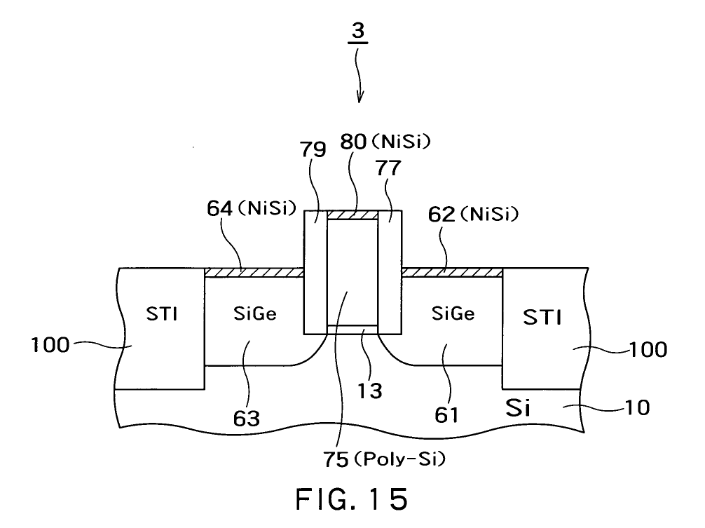

FIG. 15 is a schematic cross-sectional view illustrating an approximate configuration of the second embodiment of a semiconductor device in accordance with the present invention. The feature of a semiconductor device 3 illustrated in FIG. 15 is that the semiconductor device is provided with a gate electrode 75 formed in such a manner that a second-layer gate polysilicon is formed so as to pass through the region of a first-layer gate polysilicon sandwiched between impurity diffusion layers 61 and 63 formed of SiGe and extend perpendicularly to the paper surface, thus being integrated with the first-layer gate polysilicon. Side walls 77 and 79 are formed on the sides of the gate electrode 75 and a metal silicide 80 made of NiSi is formed in the surface layer of the gate electrode 75. In the present embodiment, the metal silicide 80 corresponds to, for example, a second metal silicide. The rest of the configuration of the semiconductor device 3 illustrated in FIG. 15 is substantially the same as that of the semiconductor device 1 illustrated in FIG. 1. Consequently, the surfaces of the silicides 62 and 64 formed respectively on the surfaces of the impurity diffusion layers 61 and 63 of the source and drain are flush with the surface of the STI 100. Thus, the top surface heights of the silicides 62 and 64 are substantially the same as that of the STI 100. In this way, the semiconductor device 3 of the present embodiment is also structured to have no SiGe facets at edges of the STI 100. Consequently, the semiconductor device 3 has been significantly improved in terms of both a characteristic of a short channel device and a junction leakage characteristic, when compared with conventional semiconductor devices.

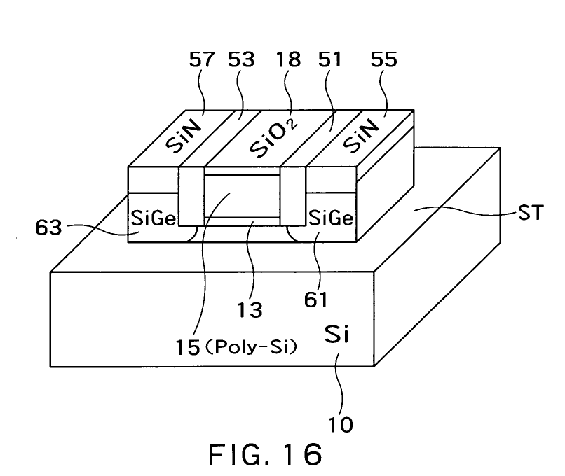

Now, a method of manufacturing the semiconductor device 3 illustrated in FIG. 15 will be described with reference to FIGS. 16 to 21.

Since the manufacturing steps from channel doping into a channel forming region to gate patterning, formation and treatment of concave portions in the impurity diffusion layer forming regions and formation of an impurity diffusion layer 60 by the epitaxial growth of SiGe are the same as those of the manufacturing method of the first embodiment described above (see FIGS. 4 to 8), the description of these manufacturing steps is omitted.

In the next step, as illustrated in FIG. 16, the impurity diffusion layers 61 and 63 are removed to a depth of approximately 30 nm from the surfaces thereof and SiN films 55 and 57 serving as hard masks are formed on the surfaces of the impurity diffusion layers 61 and 63 by depositing SiN and flattening the deposited SiN by CMP.

Then, after forming a resist adapted to the shape of the device forming region, a shallow trench ST for device isolation is formed by selectively removing the gate pattern, the side walls 51 and 53, the SiGe 61 and 63, and the hard masks 55 and 57 using an RIE process, as illustrated in FIG. 16.

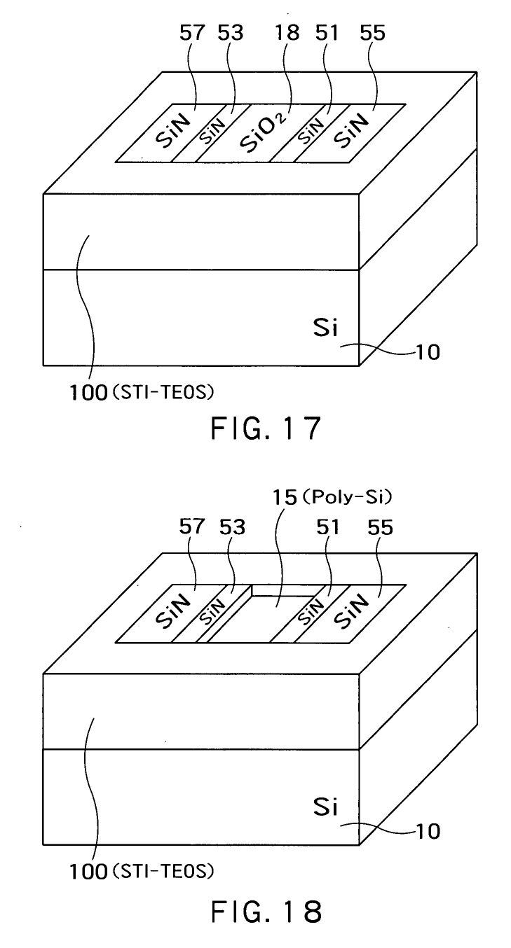

In addition, an STI 100 is formed by filling a TEOS insulating film in the formed ST and flattening the ST by CMP, as illustrated in FIG. 17.

In this way, also in the present embodiment, it is possible to prevent SiGe facets from occurring at edges of the STI since the STI is formed after forming the gate pattern and the SiGe layers of the source and drain. Consequently, there is provided a semiconductor device which has been significantly improved in terms of both a junction leakage characteristic and a characteristic of a short channel device.

In the next step, an SiO₂ film 18 above the gate polysilicon 15 is removed to expose the top face of the gate polysilicon 15, as illustrated in FIG. 18.

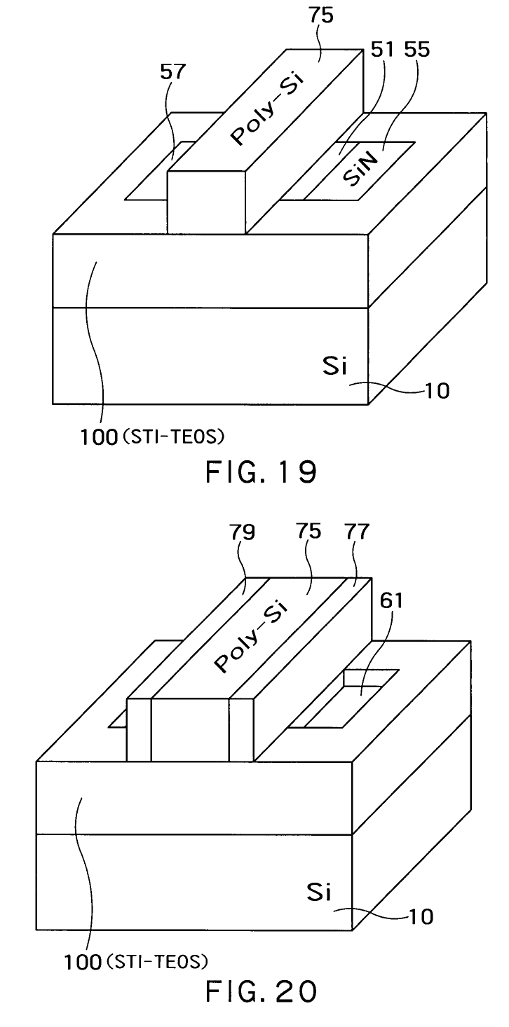

Then, by depositing the same material as the gate electrode, which is polysilicon in the present embodiment, across the entire surface of the semiconductor device and selectively removing the deposited polysilicon using photolithography and RIE, as illustrated in FIG. 19, a polysilicon 75 is formed in the second layer above the gate polysilicon 15 composing the first layer, wherein the polysilicon 75 runs over the gate polysilicon 15, extends across a region above the STI 100 along the longitudinal direction of the gate polysilicon 15, and is connected to, for example, the gate of an adjacent MIS transistor. Since the same material is used, the polysilicon 75 is integrated with the first-layer gate polysilicon 15.

Then, after forming TEOS side walls 77 and 79 on the side walls of the polysilicon 75, the SiN films 55 and 57 in the source and drain regions are removed to expose the top surfaces of the impurity diffusion layers 61 and 63, as illustrated in FIG. 20.

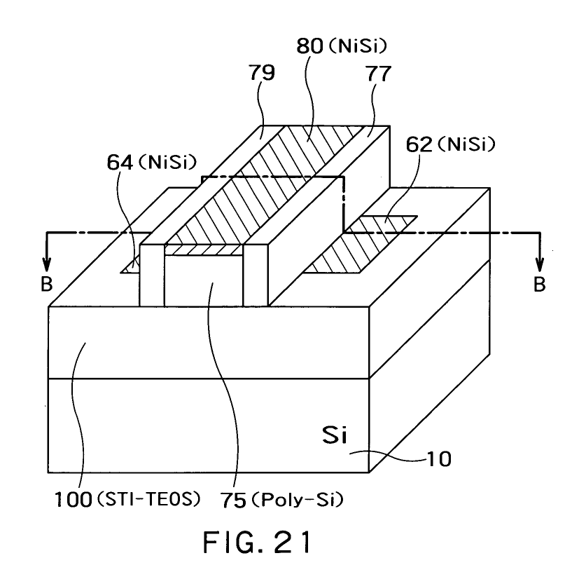

Finally, the semiconductor device 3 illustrated in FIG. 15 is obtained by sputtering a metal, for example, Ni onto the surface of the semiconductor device, performing annealing treatment and forming metal silicides 80, 62 and 64 on the surfaces of the gate electrode 75 and the impurity diffusion layers 61 and 63 of the source and drain, as illustrated in FIG. 21. Note here that FIG. 15 is a cross-sectional view along the cutting-plane line B-B shown in FIG. 21.

Since the manufacturing method of the present embodiment is provided with a step of providing hard masks made of SiN films 55 and 57 on the SiGe impurity diffusion layers 61 and 63, there is obtained a structure resistant to an alignment offset, making it possible to prevent a short circuit failure from occurring between the gate and the source and between the gate and the drain.

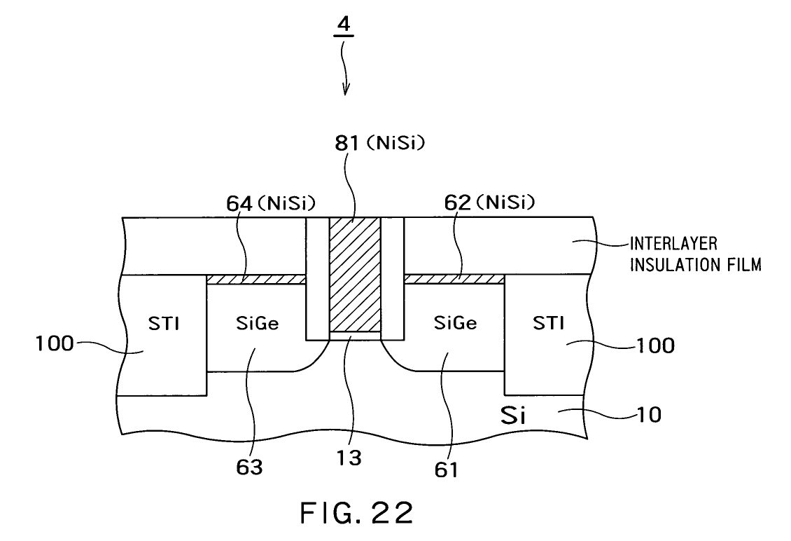

Also in the present embodiment, either a full silicidation process or a damascene process may be used when forming a gate electrode. For example, a metal gate electrode can be formed by depositing an interlayer film across the entire surface of the semiconductor device, flattening the surface by CMP, exposing the gate electrode 75 by etching back the deposited film, and then performing full silicidation or applying a damascene process after going through the step illustrated in FIG. 20. As an example of modification of the present embodiment, a semiconductor device 4 provided with a fully-silicided gate electrode 81 is illustrated in the cross-sectional view of FIG. 22. In the semiconductor device 4 illustrated in FIG. 22, the metal silicide 81 also corresponds to, for example, a second metal silicide.

### (3) Third Embodiment

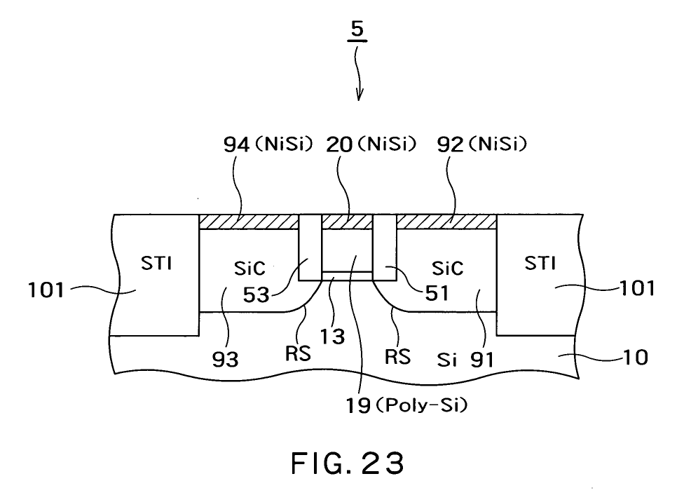

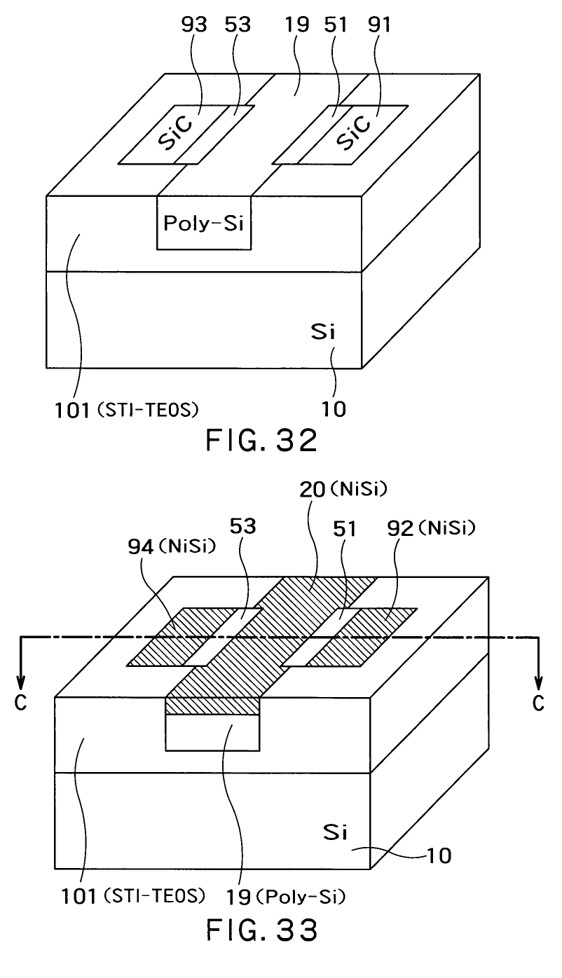

FIG. 23 is a schematic cross-sectional view illustrating an approximate configuration of the third embodiment of a semiconductor device in accordance with the present invention and is a cross-sectional view along the cutting-plane line C-C shown in FIG. 33 which will be explained later. A semiconductor device 5 illustrated in FIG. 23 differs from the above-described first embodiment in that the semiconductor device 5 is provided with an nMOSFET which includes impurity diffusion layers 91 and 93 composing a source and a drain formed by epitaxially growing SiC in concave portions RS provided in impurity diffusion layer forming regions and thereby filling the concave portions RS. The rest of the configuration of the semiconductor device 5 illustrated in FIG. 23 is substantially the same as that of the semiconductor device 1 illustrated in FIG. 1. Consequently, the surfaces of the silicides 92 and 94 on the surfaces of the impurity diffusion layers 91 and 93 of the source and drain are flush with the surface of the STI 101. Thus, the top surface heights of the metal silicides 92 and 94 are substantially the same as that of the STI 101. In addition, the top surface height of the metal silicide 20 on the surface of the gate electrode 19 is also substantially the same as that of the STI 101. In this way, the semiconductor device 5 of the present embodiment is also structured to have no SiC facets at edges of the STI 101. Accordingly, there is provided a semiconductor device which has been significantly improved in terms of both a characteristic of a short channel device and a junction leakage characteristic. In the present embodiment, the metal silicides 92 and 94 correspond to, for example, a first metal silicide.

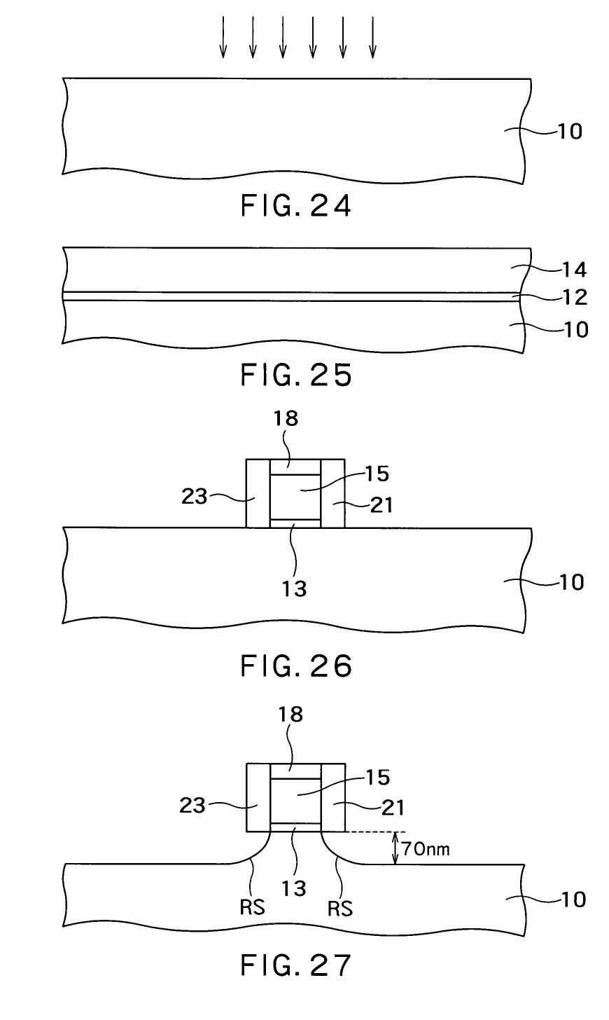

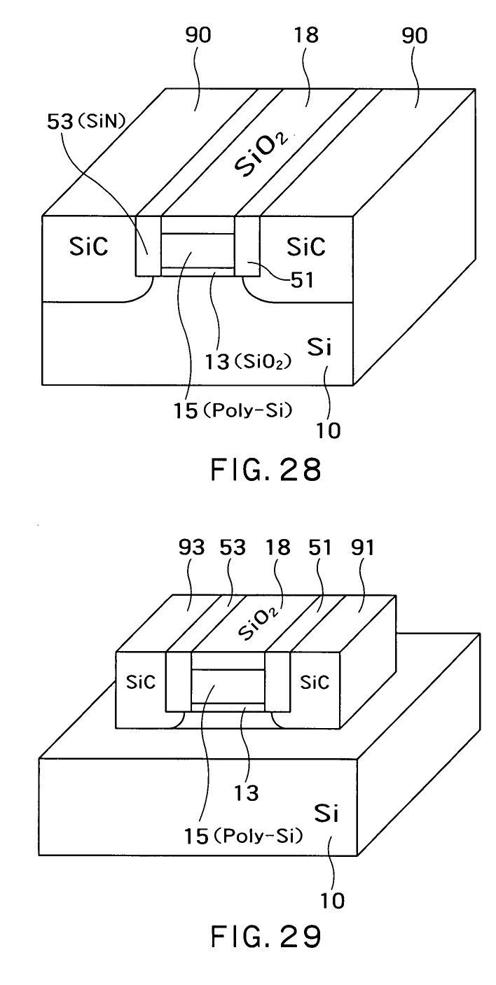

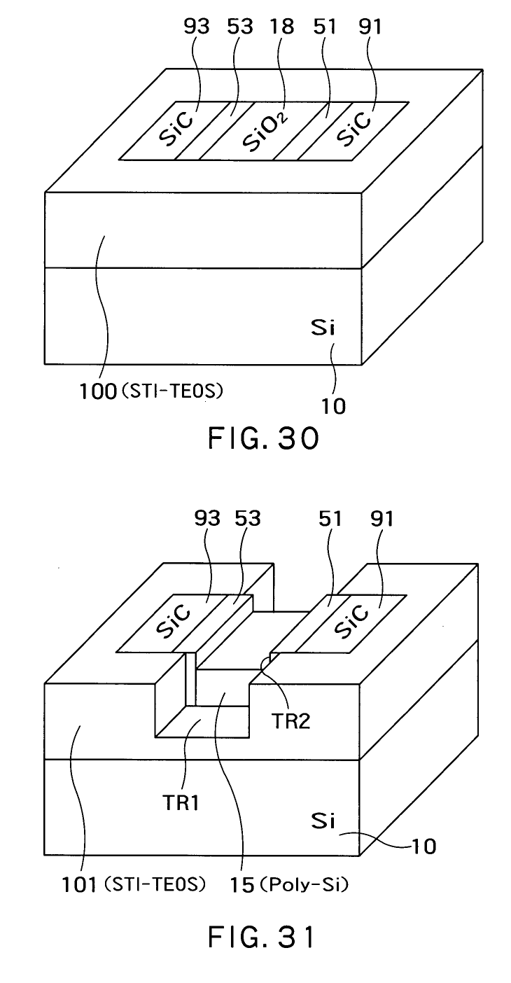

FIGS. 24 to 33 are schematic cross-sectional views or partial perspective views intended to explain a method of manufacturing the semiconductor device 5 of the present embodiment. The manufacturing method depicted by these figures is substantially the same as that of the first embodiment described above. The difference is that an impurity implanted in the channel doping shown in FIG. 24 is, for example, boron (B) ion and the impurity diffusion layers 91 and 93 are formed by the epitaxial growth of SiC in the concave portions RS formed in the impurity diffusion layer forming regions.

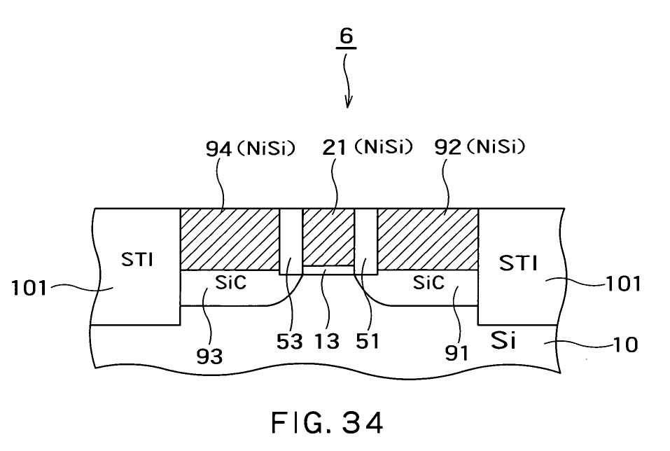

Since the semiconductors of gate, source and drain portions can be simultaneously subjected to a silicide reaction also according to the semiconductor device manufacturing method of the present embodiment, it is possible to reduce the number of process steps accordingly. Furthermore, even if the semiconductors are subjected to a full silicidation reaction, the silicides of the source and drain portions never grow too deeply. As an example of modification of the present embodiment, a semiconductor device 6 provided with a fully-silicided gate electrode 21 is illustrated in the cross-sectional view of FIG. 34. In the semiconductor device 6 illustrated in FIG. 34, the gate electrode 21 also corresponds to, for example, a second metal silicide.

When forming the gate, a damascene process may be used rather than full silicidation also in the present embodiment, as with the first embodiment described above. More specifically, by removing the gate polysilicon 19, filling a metal material in the trench thus formed, and flattening the trench by CMP in the manufacturing step illustrated in FIG. 32, it is possible to form a gate electrode made of the metal material. In this case, control of the work function (i.e., the threshold of a transistor) of the gate electrode becomes easy since a pure metal other than a silicide can be used as the metal material.

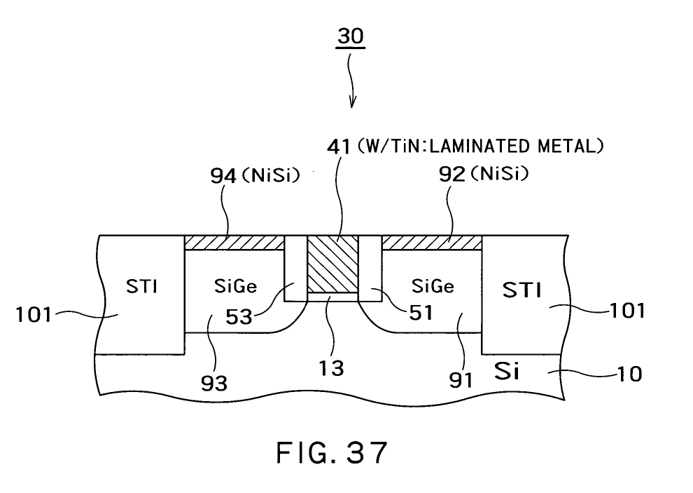

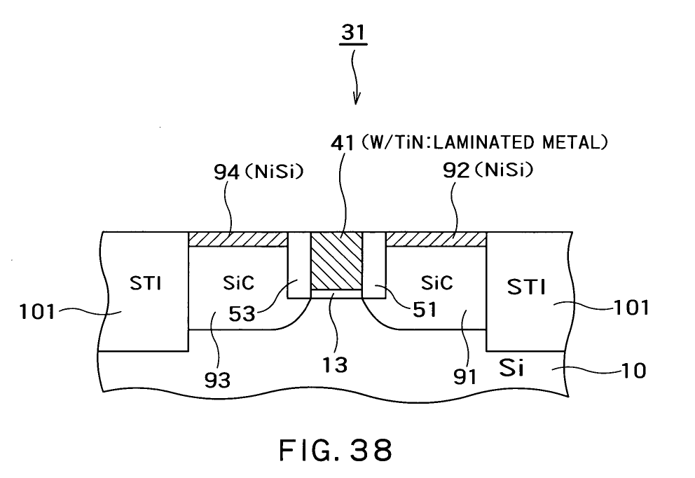

Examples of semiconductor devices provided with a gate formed with a metal material using such a damascene process as described above, are illustrated in FIGS. 37 and 38. FIG. 37 illustrates a semiconductor device 30 wherein a gate electrode 41 made of W/TiN laminated metal is formed using a damascene process for a pMISFET, whereas FIG. 38 illustrates a semiconductor device 31 wherein a gate electrode 41 made of W/TiN laminated metal is formed using a damascene process for an nMISFET.

### (4) Fourth Embodiment

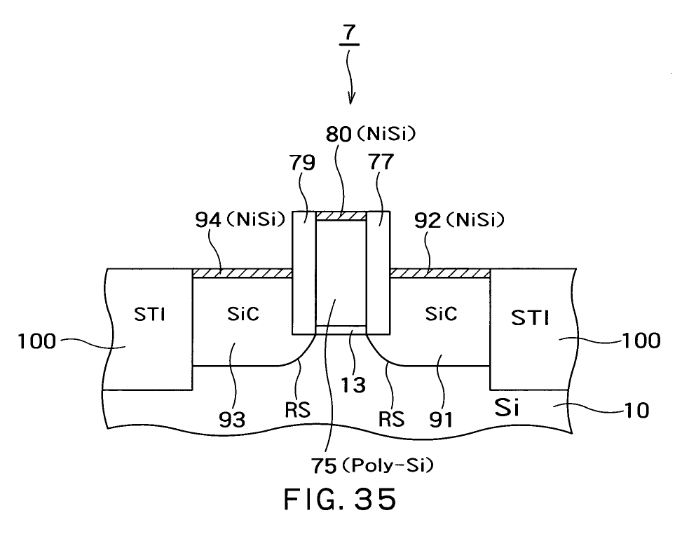

FIG. 35 is a schematic cross-sectional view illustrating an approximate configuration of the fourth embodiment of a semiconductor device in accordance with the present invention. A semiconductor device 7 illustrated in FIG. 35 differs from the above-described second embodiment in that the semiconductor device 7 is provided with an nMOSFET which includes impurity diffusion layers 91 and 93 composing a source and a drain formed by epitaxially growing SiC in concave portions RS provided in impurity diffusion layer forming regions and thereby filling the concave portions RS. The rest of the configuration of the semiconductor device 7 illustrated in FIG. 35 is substantially the same as that of the semiconductor device 3 illustrated in FIG. 15. Consequently, the surfaces of the silicides 92 and 94 on the surfaces of the impurity diffusion layers 91 and 93 of the source and drain are flush with the surface of the STI 100. Thus, the top surface heights of the silicides 62 and 64 are substantially the same as that of the STI 100. In this way, the semiconductor device 7 of the present embodiment is also structured to have no SiC facets at edges of the STI 100. Accordingly, there is provided a semiconductor device which has been significantly improved in terms of both a characteristic of a short channel device and a junction leakage characteristic.

The manufacturing method of the semiconductor device 7 illustrated in FIG. 35 is substantially the same as that of the second embodiment described above. The difference is that an impurity implanted in the channel doping shown in FIG. 4 is, for example, boron (B) ion and the impurity diffusion layers 91 and 93 are formed by the epitaxial growth of SiC embedded in the concave portions RS formed in the impurity diffusion layer forming regions. Accordingly, drawings intended to explain the manufacturing method are not attached hereto and, therefore, a reference should be made to FIGS. 4 to 8 and FIGS. 16 to 21.

Since the semiconductor device manufacturing method of the present embodiment is also provided with a step of providing hard masks made of an SiN film on the impurity diffusion layers 91 and 93 of SiC (see FIG. 16), as with the manufacturing method of the above-described second embodiment, there is obtained a structure resistant to an alignment offset, making it possible to prevent a short circuit failure from occurring between the gate and the source and between the gate and the drain.

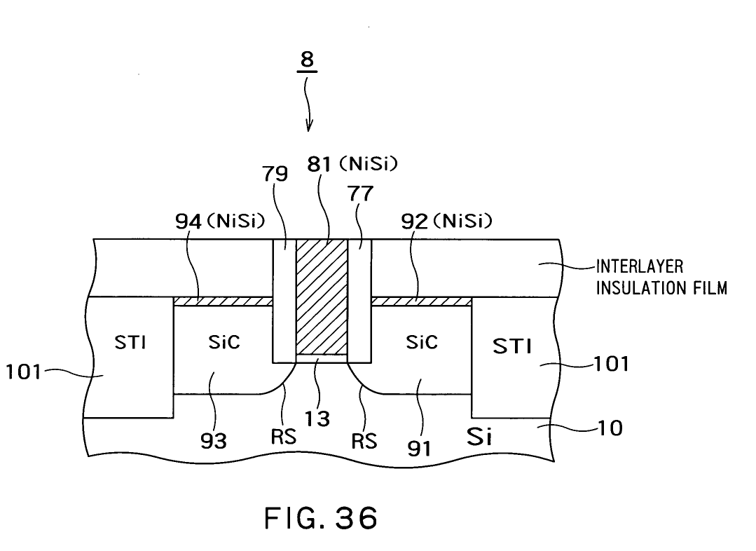

Also in the present embodiment, either a full silicidation process or a damascene process can be used when forming a gate electrode, as is described in the second embodiment. As an example of modification of the present embodiment, a semiconductor device 8 provided with a fully-silicided gate electrode 81 is illustrated in the cross-sectional view of FIG. 36. In the semiconductor device 8 illustrated in FIG. 36, the metal silicide 81 also corresponds to, for example, a second metal silicide. It is to be noted, however, that in the case of the full silicidation simultaneous silicidation both to the source/drain and the gate electrode should be avoided so that the bottom of the silicide in the region of the source/drain is made sufficiently shallow.

What is claimed is:

1. A semiconductor device comprising a MISFET, the MISFET including:
a shallow trench insulator (STI) formed in a surface layer of a semiconductor substrate to define a device forming region;
a gate electrode formed above the device forming region via a gate insulating film;
impurity diffusion layers composing a source and a drain formed in the surface layer of the device forming region using SiGe or SiC so as to sandwich the gate electrode; and
a first metal silicide formed on the surfaces of the impurity diffusion layers;
wherein the surface height of the STI is substantially the same as the height of the first metal silicide.

2. The semiconductor device according to claim 1, further comprising a second metal silicide formed at least in the surface layer of the gate electrode.

3. The semiconductor device according to claim 2, wherein the height of the second metal silicide is substantially the same as the surface height of the STI.

4. The semiconductor device according to claim 1, wherein the gate electrode is formed of a metal.

5. The semiconductor device according to claim 1,
wherein the gate electrode has a two-layer structure composed of a first layer and a second layer integrated with the first layer, the gate electrode of the first layer being formed in a striped shape so as to be sandwiched between the impurity diffusion layers and the gate electrode of the second layer being formed on the first layer and the STI along the longitudinal direction of the striped shape of the first layer.

6. The semiconductor device according to claim 1, comprising a first MISFET and a second MISFET,
wherein the impurity diffusion layers of the first MISFET are formed using SiGe and the impurity diffusion layers of the second MISFET are formed using SiC.

7. A method of manufacturing a semiconductor device comprising:
forming a gate electrode of a conductive material above a device forming region of a semiconductor substrate via a gate insulating film;
forming concave portions in an impurity diffusion layer forming region by selectively removing a surface layer of the device forming region so as to sandwich the gate electrode as viewed from the top;
forming SiGe layers composing a source and a drain in impurity diffusion layer forming regions by epitaxially growing SiGe onto the concave portions; and
forming a shallow trench insulator (STI) to isolate the device forming region after forming the SiGe layers.

8. The method of manufacturing a semiconductor device according to claim 7, further comprising simultaneously siliciding at least the surface layer of the gate electrode and the surface layers of the SiGe layers.

9. The method of manufacturing a semiconductor device according to claim 7, further comprising:
depositing, after forming the STI, the same conductive material as the conductive material to form the gate electrode and
forming a second-layer gate electrode on a first-layer gate electrode sandwiched between the SiGe layers and on the STI by patterning using a resist, so that the second-layer gate electrode is formed along the longitudinal direction of the first-layer gate electrode and integrated with the first-layer gate electrode.

10. The method of manufacturing a semiconductor device according to claim 9, further comprising providing hard masks on surfaces of the SiGe layers before the gate electrode of the second layer is formed.

11. A method of manufacturing a semiconductor device comprising:
forming a gate electrode of a conductive material above a device forming region of a semiconductor substrate via a gate insulating film;
forming concave portions in an impurity diffusion layer forming region by selectively removing a surface layer of the device forming region so as to sandwich the gate electrode as viewed from the top;
forming SiC layers composing a source and a drain in impurity diffusion layer forming regions by epitaxially growing SiC onto the concave portions; and
forming a shallow trench insulator (STI) to isolate the device forming region after forming the SiC layers.

12. The method of manufacturing a semiconductor device according to claim 11, further comprising simultaneously siliciding at least the surface layer of the gate electrode and the surface layers of the SiC layers.

13. The method of manufacturing a semiconductor device according to claim 11, further comprising:
depositing, after forming the STI, the same conductive material as the conductive material to form the gate electrode and
forming a second-layer gate electrode on a first-layer gate electrode sandwiched between the SiC layers and on the STI by patterning using a resist, so that the second-layer gate electrode is formed along the longitudinal direction of the first-layer gate electrode and integrated with the first-layer gate electrode.

14. The method of manufacturing a semiconductor device according to claim 13, further comprising providing hard masks on surfaces of the SiC layers before the gate electrode of the second layer is formed.

15. A method of manufacturing a semiconductor device comprising:
provisionally forming a gate electrode above a device forming region of a semiconductor substrate via a gate insulating film;
forming concave portions in an impurity diffusion layer forming region by selectively removing a surface layer of the device forming region so as to sandwich the provisional gate electrode as viewed from the top;
forming SiGe layers composing a source and a drain in the impurity diffusion layer forming region by epitaxially growing SiGe onto the concave portions;
forming a shallow trench insulator (STI) to isolate the device forming region after forming the SiGe layers; and
forming a gate electrode after removing the provisional gate electrode, filling a metal material in a trench thus formed, and flattening a surface of the metal filled in the trench.

16. A method of manufacturing a semiconductor device comprising:
provisionally forming a gate electrode above a device forming region of a semiconductor substrate via a gate insulating film;
forming concave portions in an impurity diffusion layer forming region by selectively removing a surface layer of the device forming region so as to sandwich the provisional gate electrode as viewed from the top;
forming SiC layers composing a source and a drain in the impurity diffusion layer forming region by epitaxially growing SiC onto the concave portions;
forming a shallow trench insulator (STI) to isolate the device forming region after forming the SiC layers; and
forming a gate electrode after removing the provisional gate electrode, filling a metal material in a trench thus formed, and flattening a surface of the metal filled in the trench.
